(19) United States
(12) Patent Application Publication
(10) Pub. No.: US 2018/0049316 A1
(43) Pub. Date: Feb. 15, 2018

(54) CIRCUIT STRUCTURE

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventors: Yu MURONOI, Yokkaichi, Mie (JP); Tou CHIN, Yokkaichi, Mie (JP)

(21) Appl. No.: 15/557,142

(22) PCT Filed: Mar. 15, 2016
(86) PCT No.: PCT/JP2016/058118

§ 371 Date: Sep. 11, 2017

(30) Foreign Application Priority Data
Mar. 25, 2015 (JP) 2015-062951

(51) Int. Cl. H05K 1/02; H05K 3/34; H05K 1/18

(52) U.S. Cl. CPC H05K 1/0271; H05K 1/181; H05K 3/341; H05K 2201/10227; H05K 2201/10272; H05K 2201/068

(57) ABSTRACT

A circuit structure that has a high rigidity, has high cooling performance for an electronic component, and can reduce electrical resistance between the electronic component and a bus bar. The circuit structure has a circuit board, bus bars, a binding material, metal chips, and electronic components. The circuit board has opening portions that penetrate in the thickness direction. The bus bars are overlaid on the circuit board. The binding material is interposed between the circuit board and the bus bars and binds them. The metal chips are arranged inside the opening portions and also placed on the bus bars. The metal chips each have a top face, which is located in approximately the same plane as an opening end face of an opening portion, and a bottom face, approximately the entire surface of which is joined to a bus bar. The electronic components are soldered to the circuit board and the top faces of the metal chips.

### CROSS REFERENCE TO RELATED APPLICATIONS

This application claims the priority of Japanese patent application JP2015-062951 filed on Mar. 25, 2015, the entire contents of which are incorporated herein.

### TECHNICAL FIELD

The present invention relates to a circuit structure.

### BACKGROUND ART

A circuit structure that constitutes a power circuit such as an inverter or a converter is incorporated in an electrical connection box or the like for distributing power from a vehicle-mounted power source to various electrical components, for example. The circuit structure has a circuit board and a plurality of bus bars that are adhered to the circuit board. Also, electronic components that constitute the power circuit are mounted on the circuit structure.

For example, a circuit structure disclosed in Patent Document 1 (JP 2006-5096A) has a circuit board, in which an opening portion is formed, and a bus bar provided with a connection projection portion that projects into the opening portion, and the connection projection portion and a terminal of an electronic component are soldered together. This circuit structure makes it possible to visually check the state of the solder more easily than in the case where the bus bar does not have the connection projection portion. Accordingly, it is possible to improve connection reliability for the electronic component.

Also, by providing the bus bar with the connection projection portion, it is possible to easily increase the thickness of the circuit board without impairing connection reliability for the electronic component. As a result, the rigidity of the circuit structure can be increased compared to conventional technology, thus making it possible to also expect an effect of reducing warping and distortion of the circuit structure.

### SUMMARY

However, conventional circuit structures still have room for improvement regarding the following points. For example, in the case of providing the connection projection portion with use of a method such as press work or cut-and-raise as described in Patent Document 1, there is a risk of a crack forming in the bus bar if the height of the connection projection portion is set too high. Accordingly, in this case, there is a limit to the height that can be set for the connection projection portion. Due to the height of the connection projection portion being limited in view of suppressing the formation of cracks in the bus bar, the thickness of the circuit board is consequently limited. Accordingly, in the case of providing the connection projection portion using a method such as press work, it is difficult to improve the rigidity of the circuit structure by increasing the thickness of the circuit board.

Also, in the case of providing the connection projection portion by pressing a conductor into the bus bar, the junction area between the conductor and the bus bar tends to be relatively small. The electrical resistance and heat resistance between the conductor and the bus bar therefore tend to increase. Accordingly, in the case of providing the connection projection portion by pressing a conductor into the bus bar, there is a risk of problems occurring such as insufficient cooling of the electronic component or an increase in electrical resistance between the electronic component and the bus bar.

As described above, with conventional circuit rigid bodies, there is still room for improvement in terms of improving cooling performance for the electronic component and reducing electrical resistance between the electronic component and the bus bar in the case of making a further improvement to rigidity.

The present design was achieved in light of this background, and an object of the present design is to provide a circuit structure that has a high rigidity, has high cooling performance for an electronic component, and can reduce electrical resistance between the electronic component and a bus bar.

A circuit structure according to one aspect of the present design includes:

a circuit board having opening portions that penetrate in a thickness direction;

a plurality of bus bars that are constituted by conductors and are overlaid on the circuit board;

a binding material that is interposed between the circuit board and the plurality of bus bars and binds them together;

metal chips that are arranged in the opening portions and are placed on the bus bars; and

electronic components that are soldered to both the circuit board and the metal chips,

wherein the metal chips each have a top face that is located in approximately the same plane as an opening end face of an opening portion among the opening portions, and a bottom face, approximately an entirety of a surface of the bottom face being joined to a bus bar among the bus bars, and

the electronic components are soldered to the top faces of the metal chips.

The circuit structure has the metal chips that are arranged in the opening portions and are placed on the bus bars. Also, the metal chips each have a top face, which is located in approximately the same plane as an opening end face of an opening portion, and a bottom face, approximately the entire surface of which is joined to a bus bar. In this way, the circuit structure is constituted by joining the bus bars and the metal chips that are prepared separately. For this reason, by using metal chips that correspond to the thickness of the circuit board, it is possible to easily cause the positions of the top faces to match the opening end faces of the opening portions. Accordingly, with this circuit structure, the thickness of the circuit board can be easily increased, thus making it possible to improve the rigidity.

Also, in the circuit structure, approximately the entirety of the surfaces of the bottom faces of the metal chips are joined to the bus bars, thus making it possible to easily increase the junction area between the metal chips and the bus bars. As a result, with this circuit structure, it is possible to efficiently cool the electronic components, and it is also possible to reduce electrical resistance between the electronic components and the bus bars.

As described above, the circuit structure has a high rigidity, has high cooling performance for the electronic component, and can reduce electrical resistance between the electronic component and the bus bar.

### BRIEF DESCRIPTION OF DRAWINGS

FIG. 1 is a perspective view showing a relevant portion of a circuit structure in a first embodiment.

FIG. 2 is a partial cross-sectional view of the relevant portion of the circuit structure in the first embodiment.

FIG. 3 is a partial cross-sectional view of a relevant portion of a circuit structure to which metal chips and bus bars have been soldered in a second embodiment.

### DESCRIPTION OF EMBODIMENTS

In the above-described circuit structure, a metal that is superior in terms of electrical conductivity and heat conductivity can be applied as the material constituting the metal chips. Specifically, copper, a copper alloy, aluminum, an aluminum alloy, iron, an iron alloy, zinc, tungsten, gold, silver, tin, nickel, or the like can be applied as the material constituting the metal chips.

It is preferable that the metal chips are constituted by a metal having a linear expansion coefficient of 15 to 45 ppm/° C. A glass epoxy board having an FR-4 (Flame Retardant type 4) base material or the like is often employed as the circuit boards used in circuit structures. These circuit boards have a linear expansion coefficient of approximately 20 to 50 ppm/° C. in the thickness direction in the temperature range in which the circuit structures are used.

Accordingly, by using metal chips whose linear expansion coefficient is in the above-specified range, it is possible to bring the value of the linear expansion coefficient of the circuit board in the thickness direction close to the linear expansion coefficient of the metal chips. As a result, it is possible to reduce the amount of thermal stress that is applied to the solder for joining electronic components to the metal chips and the solder for joining electronic components to the circuit board, thus making it possible to further improve connection reliability for the electronic components.

If the linear expansion coefficient of the metal chips falls outside the above-specified range, the amount of thermal stress applied to the above-described solder tends to increase. If the amount of thermal stress applied to the solder increases, cracks or the like tend to form in the solder, and thus there is a risk of inviting an electronic component connection failure. In order to suppress such problems, it is preferable to use metal chips having a linear expansion coefficient in the above-specified range. From the same viewpoint, it is further preferable that the linear expansion coefficient of the metal chips is in the range of 15 to 25 ppm/° C.

### EMBODIMENTS

### First Embodiment

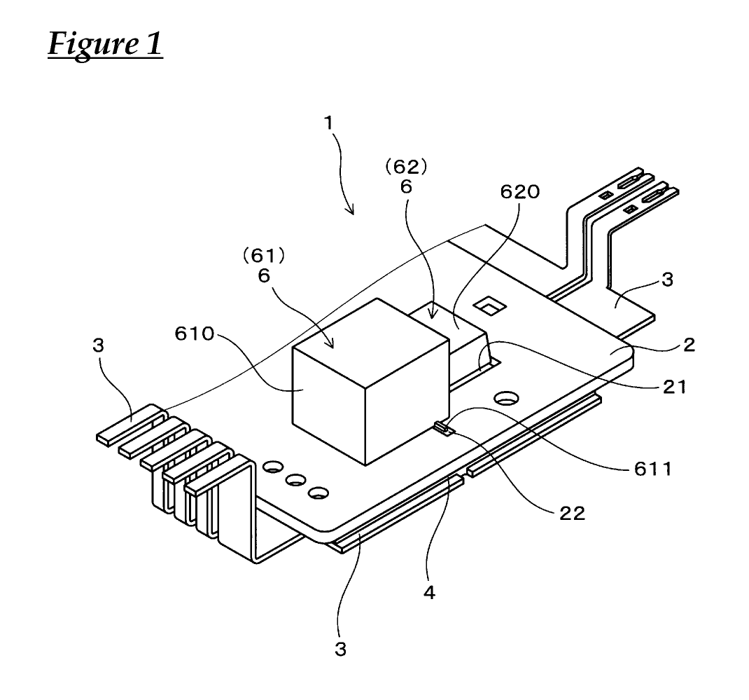

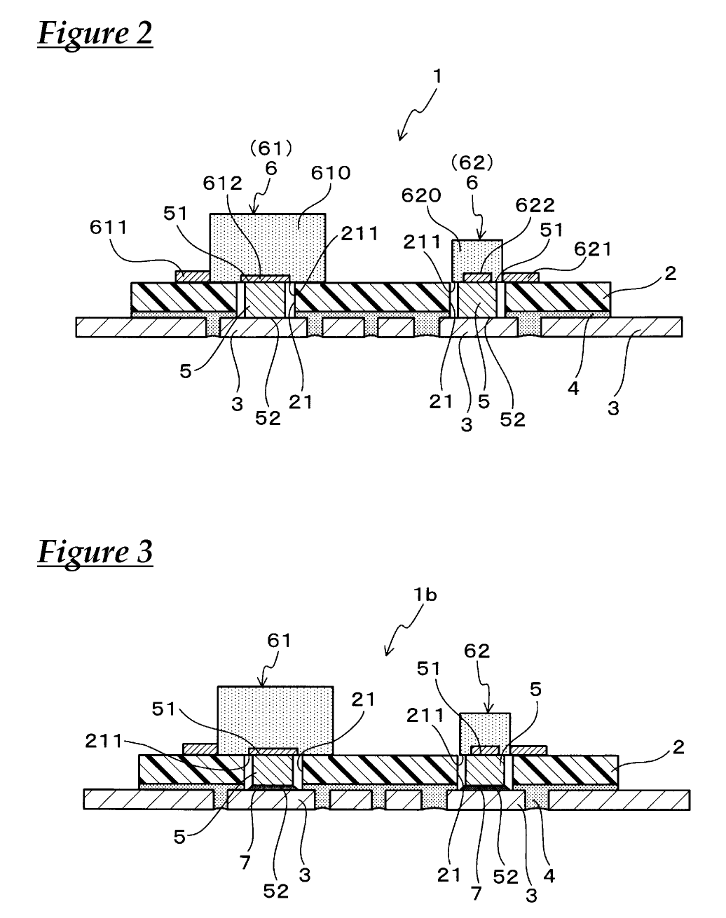

An embodiment of the above-described circuit structure will be described below with reference to the drawings. As shown in FIGS. 1 and 2, a circuit structure 1 has a circuit board 2, a plurality of bus bars 3, a binding material 4, metal chips 5, and electronic components 6. As shown in FIG. 2, the circuit board 2 has opening portions 21 that penetrate in the thickness direction. The bus bars 3 are constituted by conductors, and are overlaid on the circuit board 2. The binding material 4 is interposed between the circuit board 2 and the bus bars 3, and these members are bonded together by the binding material 4. The metal chips 5 are arranged inside the opening portions 21 and also placed on the bus bars 3. The electronic components 6 are soldered (not shown) to both the circuit board 2 and the metal chips 5.

As shown in FIG. 2, the metal chips 5 each have a top face 51, which is located in approximately the same plane as an opening end face 211 of an opening portion 21, and a bottom face 52, approximately the entire surface of which is joined to a bus bar 3. The electronic components 6 are soldered (not shown) to the top faces 51 of the metal chips 5. The circuit structure 1 of the present embodiment will be described in detail below.

The bus bars 3 are constituted by copper or a copper alloy. The bus bars 3 of the present embodiment can be produced by, for example, appropriately performing punch processing, bend processing, or the like on a copper plate or a copper alloy plate.

The circuit board 2 has a plurality of opening portions 21 that penetrate in the thickness direction. The opening portions 21 are arranged over the bus bars 3 as shown in FIG. 2, and are configured such that the metal chips 5 can be placed inside the opening portions 21. Note that the circuit board 2 of the present embodiment is a glass epoxy board made of an FR-4 material. The linear expansion coefficient of the FR-4 material in the thickness direction at approximately room temperature is typically around 30 ppm/° C.

A conventionally known binding material 4 such as thermosetting epoxy resin can be used as the binding material 4 that binds the bus bars 3 and the circuit board 2.

The metal chips 5 arranged inside the opening portions 21 of the circuit board 2 have approximately the same thickness as the circuit board 2. Also, while arranged inside the opening portions 21, the metal chips 5 face the peripheral side faces of the circuit board 2 with gaps therebetween. Note that metal chips 5 of the present embodiment are constituted by brass. The linear expansion coefficient of brass is typically around 21 ppm/° C.

In the present embodiment, the metal chips 5 are directly joined to the bus bars 3 by ultrasonic welding. Specifically, the metal chips 5 of the present embodiment are placed on the bus bars 3, and then joined to the bus bars 3 by pressing the top faces 51 while applying ultrasound.

Examples of the electronic components 6 that are soldered to the circuit board 2 and the metal chips 5 include switching elements such as a mechanical relay switch 61 and a semiconductor switching element 62. The mechanical relay switch 61 has a control terminal 611 that receives a switch signal for controlling contact switching and a main terminal 612 that conducts current to the bus bars 3 in accordance with the contact switch state. As shown in FIGS. 1 and 2, a main body portion 610 of the mechanical relay switch 61 is placed on the circuit board 2. The control terminal 611 is soldered to a land 22 of the circuit board 2. Also, the main terminal 612 is soldered to the top face 51 of a metal chip 5, and is electrically connected to a bus bar 3 via the metal chip 5.

A MOSFET (Metal-Oxide-Semiconductor Field-Effect Transistor) or the like can be used as the semiconductor switching element 62. As shown in FIG. 2, a main body portion 620 of the semiconductor switching element 62 is placed on a metal chip 5. A gate terminal 621 of the semiconductor switching element 62 is soldered to a land 22 of the circuit board 2. Also, a source terminal 622 and a drain terminal (not shown) of the semiconductor switching element 62 are soldered to the top face 51 of a metal chip 5.

Note that although not shown, electronic components other than the switching elements described above are also mounted on the circuit board 2 of the present embodiment. Examples of electronic components that are mounted on the circuit board 2 include resistors, inductors, capacitors, and diodes. These electronic components configure a control circuit, which is part of the power circuit, on the circuit board 2. Driving of the mechanical relay switch 61 and the semiconductor switching element 62 is controlled by switch signals or the like that are output from the control circuit.

In the circuit structure 1 of the present embodiment, the metal chips 5 and the bus bars 3 are directly joined without a joining material such as solder therebetween. For this reason, the metal chips 5 and the bus bars 3 can be joined firmly. As a result, the joined state of the metal chips 5 and the bus bars 3 can be maintained over a long period, and connection reliability can be improved.

Also, in the circuit structure 1 of the present embodiment, a metallic bond is formed between the metal chips 5 and the bus bars 3, thus making it possible to further reduce thermal resistance and electrical resistance between them. Accordingly, the circuit structure 1 has high cooling performance for the electronic components 6, and can also reduce electrical resistance between the electronic components 6 and the bus bars 3.

### Second Embodiment

The present embodiment shows an example of a circuit structure 1b in which the metal chips 5 and the bus bars 3 are joined using an electrically conductive joining material. As shown in FIG. 3, in the circuit structure 1b of the present embodiment, a joining material 7 is interposed between the metal chips 5 and the bus bars 3, and the metal chips 5 are joined to the bus bars 3 via the joining material 7.

An electrically conductive material such as solder or a metal nano paste can be used as the joining material 7. Also, in the case of using solder as the joining material 7, the metal chips 5 and the bus bars 3 can be joined by various methods such as reflow soldering, hot pressing, and ultrasonic soldering. Other aspects are similar to the first embodiment. Note that reference signs used in FIG. 3 that are the same as reference signs used in the first embodiment denote constituent elements or the like that are same as in the first embodiment unless described otherwise in particular.

In the case where the joining material 7 is used when joining the metal chips 5 and the bus bars 3 as in the present embodiment, these members can be joined easily. As a result, the yield of the circuit structure 1b can be improved easily.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

1. A circuit structure comprising:
a circuit board having opening portions that penetrate in a thickness direction;
a plurality of bus bars that are constituted by conductors and are overlaid on the circuit board;
a binding material that is interposed between the circuit board and the plurality of bus bars and binds them together;
metal chips that are arranged in the opening portions and are placed on the bus bars; and
electronic components that are soldered to both the circuit board and the metal chips,
wherein the metal chips each have a top face that is located in approximately the same plane as an opening end face of an opening portion among the opening portions, and a bottom face, approximately an entirety of a surface of the bottom face being joined to a bus bar among the bus bars, and
the electronic components are soldered to the top faces of the metal chips.

2. The circuit structure according to claim 1, wherein the metal chips are constituted by a metal having a linear expansion coefficient of 15 to 45 ppm/° C.

3. The circuit structure according to claim 1, wherein the metal chips are directly joined to the bus bars.

4. The circuit structure according to claim 1, wherein the circuit structure has a joining material that joins the metal chips and the bus bars, and the joining material is electrically conductive.

5. The circuit structure according to claim 1, wherein a thickness of the circuit board is greater than or equal to 1.2 mm.
